(19) United States
(12) Patent Application Publication
(10) Pub. No.: US 2023/0400759 A1
(43) Pub. Date: Dec. 14, 2023

(54) PHOTOMASK DESIGN CORRECTION METHOD

(71) Applicant: United Microelectronics Corp., Hsinchu (TW)

(72) Inventors: Min Cheng Yang, Tainan City (TW); Wei Cyuan Lo, Taichung City (TW); Yung-Feng Cheng, Kaohsiung City (TW)

(73) Assignee: United Microelectronics Corp., Hsinchu (TW)

(21) Appl. No.: 17/836,992

(22) Filed: Jun. 9, 2022

(51) Int. Cl. G03F 1/36; G03F 1/70; G03F 1/72

(52) U.S. Cl. CPC G03F 1/36; G03F 1/72; G03F 1/70

(57) ABSTRACT

A photomask design correction method is provided. The photomask design correction method includes the following steps. A layer information data is provided. An OPC process is performed on the layer information data to obtain a first photomask data. A photomask is fabricated based on the first photomask data. A pattern information data of the photomask is obtained after the photomask is fabricated. The difference between the pattern information data and a database of the OPC process is analyzed. An OPC model of the OPC process is corrected based on the difference to obtain a corrected OPC model. The OPC process is performed using the corrected OPC model on the layer information data to obtain a second photomask data.

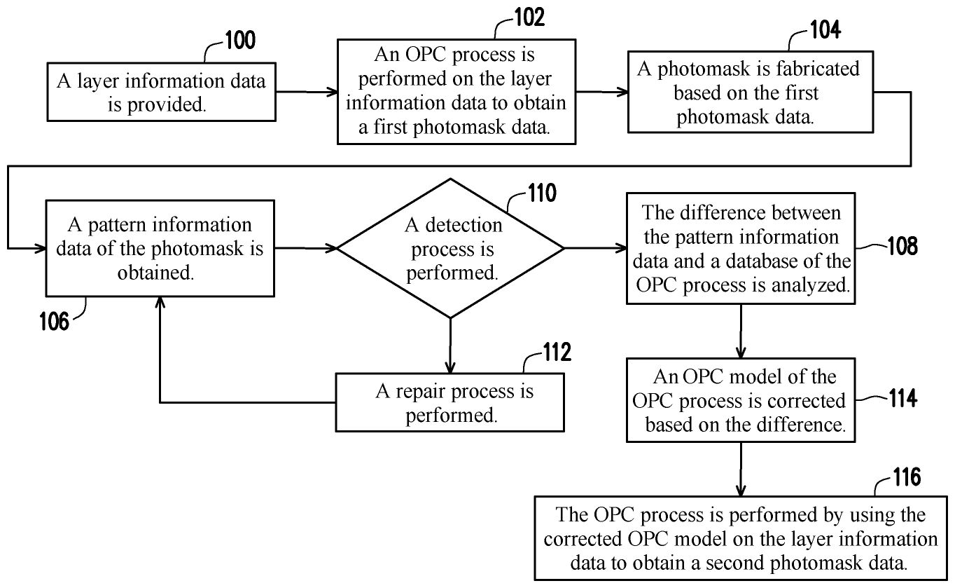

### BACKGROUND

### Technical Field

The present invention relates to a design method in a semiconductor process, and particularly to a photomask design correction method.

### Description of Related Art

In the semiconductor process, a photomask is used to define a pattern on a photoresist layer in the lithography process. Generally, during the fabrication of a photomask, an optical proximity correction (OPC) process is performed on a layer information about a patterned photoresist layer to obtain a photomask data. Then, the photomask data may be provided to a photomask house to fabricate a photomask which is used to define the patterned photoresist layer. However, depending on a pattern with a specific shape, a change of a pattern density, a specific position, such as a corner, of a pattern, parameters of the process of the photomask house etc., the actual pattern of the fabricated photomask may not be the same as the predetermined photomask pattern. In addition, difference between the actual patterns of two photomasks fabricated by two different photomask houses may be great.

### SUMMARY

The present invention provides a photomask design correction method, in which a pattern information data of a fabricated photomask is obtained, the difference between the pattern information data and the database of the OPC process is analyzed, and the OPC model of the OPC process is corrected based on the difference.

A photomask design correction method of the present invention includes the following steps. A layer information data is provided. An OPC process is performed on the layer information data to obtain a first photomask data. A photomask is fabricated based on the first photomask data. A pattern information data of the photomask is obtained after the photomask is fabricated. The difference between the pattern information data and a database of the OPC process is analyzed. An OPC model of the OPC process is corrected based on the difference to obtain a corrected OPC model. The OPC process is performed using the corrected OPC model on the layer information data to obtain a second photomask data.

In an embodiment of the photomask design correction method of the present invention, the pattern information data includes a pattern critical dimension data, a pattern image data, a pattern profile data or a combination thereof.

In an embodiment of the photomask design correction method of the present invention, further includes a detection process on the pattern information data of the photomask after the first photomask data is obtained and before the photomask is fabricated.

In an embodiment of the photomask design correction method of the present invention, further includes a repair process on the pattern information data of the photomask after the detection process and before the photomask is fabricated.

In an embodiment of the photomask design correction method of the present invention, the photomask is fabricated based on the first photomask data in a photomask house.

In an embodiment of the photomask design correction method of the present invention, the pattern information data of the photomask is obtained in the photomask house.

Based on the above, in the present invention, after a photomask is fabricated, the pattern information data of the fabricated photomask is obtained, the difference between the pattern information data and the database of the OPC process is analyzed, and the OPC model of the OPC process is corrected based on the difference. Therefore, when the OPC process is performed by using the corrected OPC model on the layer information data, a photomask data which matches the desired pattern of a photomask may be obtained, and thus a photomask with a desired pattern may be fabricated.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIGURE is a process flow of a photomask design correction method according to an embodiment of the present invention.

### DESCRIPTION OF THE EMBODIMENTS

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

FIGURE is a process flow of a photomask design correction method according to an embodiment of the present invention. The photomask design correction method is suitable for fabricating a photomask which has a pattern same as a predetermined photomask pattern.

Referring to FIGURE, first, in the step 100, a layer information data is provided. The layer information data may be a data about a pattern of a predetermined patterned photoresist layer. In the present embodiment, the layer information data may include a pattern critical dimension (CD) data, a pattern profile data or a combination thereof. In one embodiment, the layer information data may be obtained from a customer, but the present invention is not limited thereto.

Next, in the step 102, the layer information data is transferred to an OPC process stage. In the OPC stage, an OPC process may be performed on the layer information data according to an OPC database and an OPC model to correct the layer information data for the fabrication of a photomask. After the OPC process, a first photomask data may be obtained. The first photomask data may be used to fabricate a photomask corresponding to the layer information data. In the present embodiment, after the first photomask data is obtained, the first photomask data may be sent to a photomask house for the fabrication of the photomask corresponding to the layer information data, but the present invention is not limited thereto.

Then, in the step 104, a photomask is fabricated based on the first photomask data. In the present, the photomask is fabricated based on the first photomask data in the photomask house. Due to a pattern with a specific shape, a change of a pattern density, a specific position, such as a corner, of a pattern, parameters of the process of the photomask house etc., the actual pattern of the fabricated photomask may not be the same as the predetermined photomask pattern. That is, the fabricated photomask may be different from the photomask corresponding to the layer information data. When a patterned layer formed by the above fabricated photomask, the pattern of the patterned layer may not be the same as the predetermined pattern. To avoid the above problem, a correcting process is needed.

In the present embodiment, in the step 106, after the photomask is fabricated based on the first photomask data in the photomask house, a pattern information data of the fabricated photomask is obtained. In the present embodiment, the pattern information data of the fabricated photomask may be obtained in the photomask house, but the present invention is not limited thereto. In the other embodiments, the pattern information data of the fabricated photomask may be obtained in other places. The pattern information data may include a pattern critical dimension data, a pattern image data, a pattern profile data or a combination thereof.

After the pattern information data of the fabricated photomask is obtained, in the step 108, an analyzing process is performed. In the analyzing process, the difference between the pattern information data of the fabricated photomask and the database of the OPC process is analyzed.

In addition, in the present embodiment, before the step 108, a detection process is optionally performed after step 106. In detail, after the step 106, a detection process is performed on the pattern information data of the fabricated photomask to check the pattern information data for defects in the step 110. When the pattern information data has no defect or has a tolerable number of defects, the step 108 is then performed. Otherwise, a repair process is performed on the pattern information data of the fabricated photomask in the step 112 to obtain a new pattern information data. When the new pattern information data passes the detection process in the step 110, the new pattern information data is then analyzed in the step 108.

Nest, after the step 108, the OPC model of the OPC process is corrected based on the difference to obtain a corrected OPC model in the step 114.

Then, in the step 116, the OPC process is performed by using the corrected OPC model on the layer information data to obtain a second photomask data. In this way, the obtained second photomask data is a data corrected based on the photomask fabricated in the step 104.

Based on the above, when a photomask is fabricated based on a photomask data obtained from an OPC process, the actual pattern of the fabricated photomask may not be the same as the predetermined photomask pattern. In the present invention, after the photomask is fabricated, the pattern information data of the fabricated photomask and the database of the OPC process are compared and the difference therebetween is analyzed, and the OPC model of the OPC process is corrected based on the result from the comparison and the analysis. Therefore, when the OPC process is performed by using the corrected OPC model on the layer information data, a photomask data which matches the desired pattern of a photomask may be obtained.

Further, after the photomask design correction method of the present invention, the corrected photomask data, i.e., the second photomask data, may be sent to the photomask house for the fabrication of a photomask with a desired pattern corresponding to the layer information data.

It will be apparent to those skilled in the art that various modifications and variations may be made to the disclosed embodiments without departing from the scope or spirit of the invention. In view of the foregoing, it is intended that the invention covers modifications and variations provided that they fall within the scope of the following claims and their equivalents.

What is claimed is:

1. A photomask design correction method, comprising:
providing a layer information data;
performing an optical proximity correction (OPC) process on the layer information data to obtain a first photomask data;
fabricating a photomask based on the first photomask data;
obtaining a pattern information data of the photomask after the photomask is fabricated;
analyzing the difference between the pattern information data and a database of the OPC process;
correcting an OPC model of the OPC process based on the difference to obtain a corrected OPC model; and
performing the OPC process using the corrected OPC model on the layer information data to obtain a second photomask data.

2. The photomask design correction method of claim 1, wherein the pattern information data comprises a pattern critical dimension data, a pattern image data, a pattern profile data or a combination thereof.

3. The photomask design correction method of claim 1, further comprising a detection process on the pattern information data of the photomask after the first photomask data is obtained and before the photomask is fabricated.

4. The photomask design correction method of claim 3, further comprising a repair process on the pattern information data of the photomask after the detection process and before the photomask is fabricated.

5. The photomask design correction method of claim 1, wherein the photomask is fabricated based on the first photomask data in a photomask house.

6. The photomask design correction method of claim 5, wherein the pattern information data of the photomask is obtained in the photomask house.
